(19) United States
(12) Patent Application Publication
(10) Pub. No.: US 2021/0327969 A1
(43) Pub. Date: Oct. 21, 2021

(54) PIXEL ARRANGEMENT STRUCTURE AND DISPLAY PANEL

(71) Applicant: Xia ZHOU, (US)

(72) Inventor: Xia ZHOU, (US)

(21) Appl. No.: 16/326,024

(22) PCT Filed: Nov. 23, 2018
(86) PCT No.: PCT/CN2018/117082

§ 371 Date: Feb. 15, 2019

(51) Int. Cl. H01L 27/32

(52) U.S. Cl. CPC H01L 27/3218; H01L 27/3216

(57) ABSTRACT

The present disclosure provides a pixel arrangement structure and display panel. The pixel arrangement includes a plurality of pixel repeated combination. Each of the pixel repeated combinations includes a plurality of pixel units. In the pixel repeated combinations, the plurality of pixel units share a sub-pixel and surround a center of the sub-pixel. By utilizing the present disclosure which makes pixels of the plurality of pixel unit share one first sub-pixel, the numbers of the first sub-pixels in the pixel arrangement structure and the display panel are reduced, the resolution is enhanced, and limitation of FMM manufacture technology can be overcome.

### FIELD OF INVENTION

The present disclosure relates to a pixel arrangement, particularly to a pixel arrangement structure, and a display panel.

### BACKGROUND OF INVENTION

Organic light emitting diodes (OLED) display have advantages such as being self-luminous, wide viewing-angles, quick response times, etc. A general manufacturing method for forming red, green, and blue sub-pixels of OLED display uses deposition. In a conventional manufacturing process, sub-pixels including red sub-pixels, green sub-pixels, and blue sub-pixels of each of the pixels are arranged cyclically in sequence according to three colors. When manufacturing high-resolution display panels, three colors, red (R), green (G), and blue (B), of sub-pixels may be mixed if sub-pixels are arranged cyclically color by color because number of required R, G, B sub-pixels is extremely huge and fine metal mask (FMM) manufacture technology will limit the manufacture capacity.

Hence, a pixel arrangement is required for solving the above-mentioned problems.

### SUMMARY OF INVENTION

The present disclosure provides a pixel arrangement structure and a display panel to overcome problems of mix color and difficulties of manufacture exist in the present technology during the manufacturing process for high-resolution display panel.

The present disclosure provides a pixel arrangement structure includes a plurality of pixel repeated combinations. Each of the pixel repeated combinations includes a plurality of pixel units.

In the pixel repeated combination, the plurality of pixel units shares a sub-pixel and surrounds a center of the sub-pixel.

The pixel unit includes two pixels disposed back to back. Each of the pixels includes a first sub-pixel.

In the pixel unit, one of first the sub-pixel is disposed at the center of the pixel repeated combination and the other first sub-pixel is distant from the center of the pixel repeated combination. The plurality of the pixel units surrounding the first sub-pixels of the plurality of the pixel repeated combination is shared.

Each of the pixels repeated combination includes four pixel units. A shape of the pixel repeated combination is quadrangle. The four pixel units are disposed in areas formed by two midlines of the pixel repeated combination. The four pixel units are radially symmetrical to a cross over point of the two midlines of the pixel repeated combination.

A shape of the pixel repeated combination is rhombus having all right angles. A shape of the pixel unit is rhombus having all right angles. A shape of the first sub-pixel is square.

In the pixel arrangement structure of the present disclosure, each of the pixels of the pixel unit includes a second sub-pixel and a third sub-pixel disposed between the first sub-pixel and the second sub-pixel. A shape of the second sub-pixel is a hexagon. A shape of the third sub-pixel is an isosceles trapezoid.

Two of the pixels of the pixel units share the second sub-pixel and are symmetrical on a basis of a central axis of the second sub-pixel.

In the pixel structure of the present disclosure, sub-pixels of two adjacent pixel units in the same color are adjacent to each other.

In the pixel structure of the present disclosure, the first sub-pixel is a blue sub-pixel, the second sub-pixel is a red sub-pixel, and the third sub-pixel is a green sub-pixel.

In the pixel structure of the present disclosure, an area of the first sub-pixel is greater than an area of the second sub-pixel, and also greater than an area of the third sub-pixel.

The present disclosure further provides another pixel arrangement structure includes a plurality of pixel repeated combinations. Each of the pixel repeated combinations includes a plurality of pixel units.

The plurality of pixel units of the pixel repeated combination shares a sub-pixel

In the other pixel arrangement structure of the present disclosure, the pixel unit includes two pixels disposed back to back, wherein each of the pixels includes a first sub-pixel.

In the pixel unit, one of the first sub-pixel disposes at the center of the pixel repeated combination and the other first sub-pixel is distant from the center of the pixel repeated combination.

In the pixel repeated combinations, the first sub-pixels disposed in a center area of the pixel repeated combinations are shared

In the other pixel arrangement structure of the present disclosure, each of the pixel repeated combinations includes four pixel units. A shape of the pixel repeated combination is quadrangle. The four pixel units are disposed in the areas formed by two midlines of the pixel repeated combinations. The four pixel units are radially symmetrical to a cross over point of the two midlines of the pixel repeated combinations.

In the other pixel arrangement structure of the present disclosure, a shape of the pixel repeated combination is rhombus having all right angles, a shape of the pixel unit is rhombus having all right angles, and a shape of the first sub-pixel is square.

In the other pixel arrangement structure of the present disclosure, each of the pixels of the pixel unit includes a second sub-pixel and a third sub-pixel disposed between the first sub-pixel and the second sub-pixel. A shape of the second sub-pixel is a hexagon. A shape of the third sub-pixel is an isosceles trapezoid

In the other pixel arrangement structure of the present disclosure, two of the pixels of the pixel units share the second sub-pixel and are symmetrical on a basis of a central axis of the second sub-pixel.

In the other pixel arrangement structure, sub-pixels of two adjacent pixel units in the same color are adjacent to each other.

In the other pixel arrangement structure of the present disclosure, the first sub-pixel is a blue sub-pixel, the second sub-pixel is a red sub-pixel, and the third sub-pixel is a green sub-pixel.

In the pixel arrangement structure, an area of the first sub-pixel is greater than an area of the second sub-pixel and the third sub-pixel.

In the other pixel arrangement structure of the present disclosure, the luminous strength of the first sub-pixel is averaged from luminous of the four pixels sharing the same first sub-pixel. The luminous strength of the second sub-pixel is averaged from luminous of the two pixels sharing the same second sub-pixel.

The present disclosure further provides a display panel includes a pixel arrangement structure including a plurality of pixel repeated combinations. Each of the pixel repeated combinations includes a plurality of pixel units.

In the pixel repeated combinations, the plurality of pixel units surrounding the center of the pixel repeated combinations share a sub-pixel and surround a center of the sub-pixel.

In the display panel of the present disclosure, the pixel unit further comprises two pixels disposed back to back. Each of the pixels includes a first sub-pixel

In the display panel of the present disclosure, one of first the sub-pixel disposes at the center of the pixel repeated combination and the other first sub-pixel is distant from the center of the pixel repeated combination.

In the pixel repeated combination, the first sub-pixels surrounding the center the pixel repeated combinations are shared.

In the display panel of the present disclosure, each of the pixel repeated combinations includes four pixel units. A shape of the pixel repeated combination is quadrangle. The four pixel units are disposed in the areas formed by two midlines of the pixel repeated combinations. The four pixel units are radially symmetrical to a cross over point of the two midlines of the pixel repeated combinations.

In the display panel of the present disclosure, a shape of the pixel repeated combinations is rhombus having all right angles. A shape of the pixel unit is rhombus having all right angles, and a shape of the first sub-pixel is square.

In the display panel of the present disclosure, each of the pixels of the pixel unit includes a second sub-pixel and a third sub-pixel disposed between the first sub-pixel and the second sub-pixel. A shape of the second sub-pixel is a hexagon. A shape of the third sub-pixel is an isosceles trapezoid

In the display panel of the present disclosure, two of the pixels of the pixel units share the second sub-pixel and are symmetrical on a basis of a central axis of the second sub-pixel.

In the display panel of the present disclosure, sub-pixels of two adjacent repeated combinations in the same color are adjacent to each other.

In the display panel of the present disclosure, the first sub-pixel is a blue sub-pixel, the second sub-pixel is a red sub-pixel, and the third sub-pixel is a green sub-pixel.

In the display panel of the present disclosure, an area of the first sub-pixel is greater than an area of the second sub-pixel and the third sub-pixel.

In the display panel of the present disclosure, the luminous strength of the first sub-pixel is averaged from luminous of the four pixels sharing the same first sub-pixel. The luminous strength of the second sub-pixel is averaged from luminous of the two pixels sharing the same second sub-pixel.

In comparison of the pixel arrangement and display panel of the present technology, the numbers of the first sub-pixels in the pixel arrangement structure and the display panel are reduced by utilizing the present disclosure which makes pixels of the plurality of pixel unit share one first sub-pixel. As a result, the resolution is enhanced and limitation of FMM manufacture technology can be overcome. In addition, problems of mixed color can be avoided because sub-pixels in the same color are neighboring. In the meanwhile, the areas of blue sub-pixels are greatest so that the efficient usage time of blue-light components is prolonged. Hence, problems of mix color and difficulty of manufacturing exist in the present technology during the manufacturing process for high-resolution display panel can be overcome.

### DESCRIPTION OF DRAWINGS

To clarify the technology method of the embodiments of the present disclosure, the following context will introduce the drawings representing the embodiments of the present disclosure. Obviously, the described drawings are only a part but not all of the drawings for exemplifying the present invention instead of limiting the present invention. For a skilled person in the art, other drawings may be obtained by referencing the drawings of the present disclosure without creative efforts.

FIG. 1 illustrates a pixel arrangement of an embodiment of the present disclosure.

FIG. 2 illustrates a structure of a pixel combination of the pixel arrangement of the embodiment of the present disclosure.

### DETAILED DESCRIPTION OF PREFERRED EMBODIMENTS

Please refer to drawings. The same reference numbers represent the same components. The following specification should be viewed as examples rather than limitations of the present disclosure.

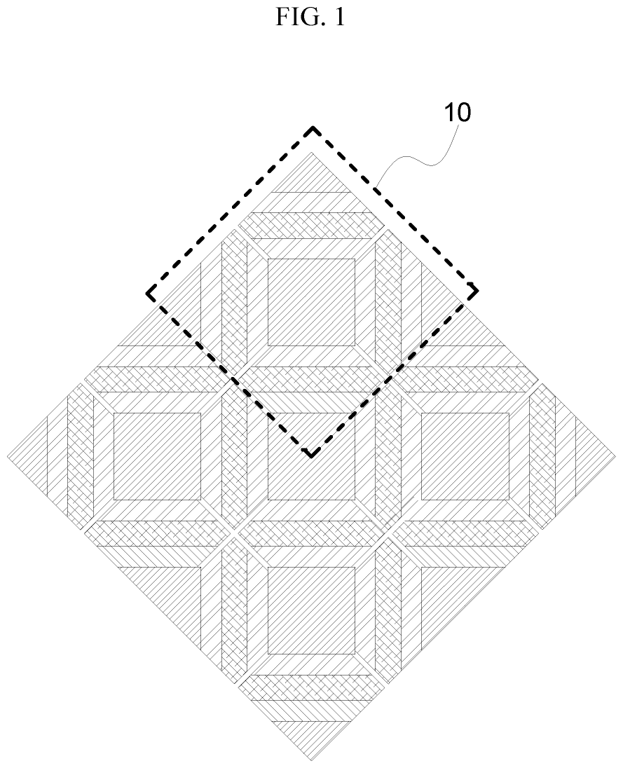

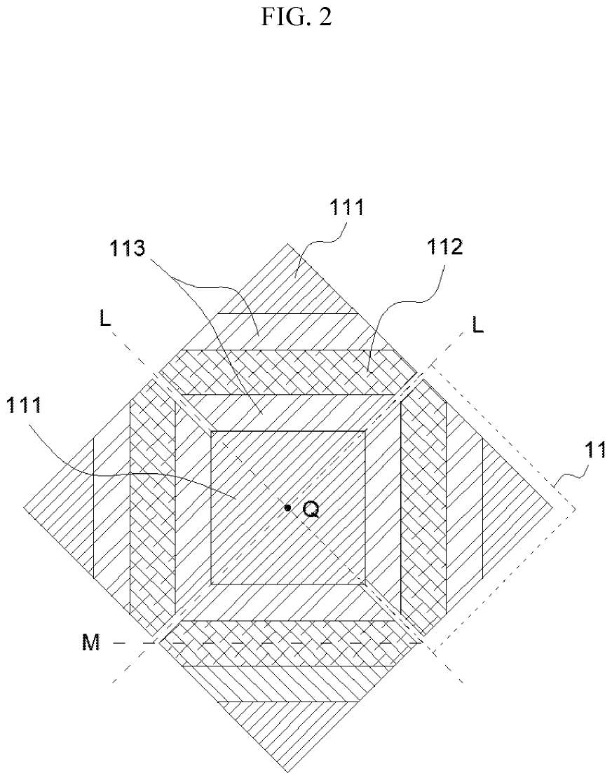

Please refer to FIG. 1 and FIG. 2. FIG. 1 illustrates a pixel arrangement of an embodiment of the present disclosure. FIG. 2 illustrates a structure of a pixel combination of the pixel arrangement of the embodiment of the present disclosure.

A pixel arrangement of the present disclosure includes a plurality of pixel repeated combinations 10. Each of the pixel repeated combinations includes a plurality of pixel units 11.

Each of the plurality of pixel repeated combinations 10 includes a plurality of pixel units 11.

In a pixel repeated combination 10, the plurality of pixel units 11 shares a sub-pixel. The plurality of pixel units is arranged surrounding a center Q of the sub-pixel.

The present disclosure makes the first sub-pixels being shared by the plurality if sub-pixels in the purpose of reducing the number of sub-pixels.

The pixel unit 11 includes two pixels disposed back to back. Each of the pixels includes a first sub-pixel 111.

In one of the pixel unit 11, one first sub-pixel 111 is disposed at a center area of pixel repeated combination 10, the other first sub-pixel 111 is disposed distantly from the center area of the pixel repeated combination 10. In a pixel repeated combination 10, the first sub-pixels of one pixel unit 11, which surround the center of the pixel repeated combination 10, are united into one sub-pixel 111 disposed in the center area.

In this embodiment, each of the pixel repeated combination 10 includes four pixel units 11. A shape of the pixel repeated combination 10 is quadrangle. The four pixel units 11 are disposed in four areas formed by two midlines L of the repeated combination. The four pixel units 11 are radially symmetrical to a cross over point (center Q) of the two midlines L of the repeated combination.

It is no doubt that one pixel repeated combination 10 can also include more or less than four pixel units.

In the present disclosure, a shape of the pixel repeated combination 10 is rhombus having all right angles. A shape of the pixel unit 11 is rhombus having all right angles. A shape of the first sub-pixel 111 is square. Hence, in a pixel repeated combination 10, the plurality of sub-pixels is disposed subsequently consistent with diagonal lines of the pixel repeated combination 10.

By uniting the first sub-pixels 111 of four pixels into one first sub-pixel 111, the total number of the first sub-pixels 111 of the pixel repeated combination 10 can be reduced by utilizing the pixel arrangement structure of the present disclosure. Thus, the number of holes on fine metal mask (FMM) can be reduced so that the stability of FMM manufacture can be enhanced. In the meanwhile, the resolution of the panel is also improved.

In the pixel arrangement structure of the present disclosure, in each of the pixel repeated combinations 10, each of pixels includes a second sub-pixel 112, which is disposed at middle of pixel unit 11, and a third sub-pixel 113 which is disposed between the second sub-pixel 112 and the first sub-pixel 111. A shape of the second sub-pixel 112 is a hexagon. A shape of the third sub-pixel 113 is an isosceles trapezoid.

Two pixels of the same pixel unit 11 share the sub-pixel 112. Two pixels of the same pixel unit 11 are symmetrical on a basis of a central axis of the second sub-pixel.

The number of the second sub-pixels is reduced because two pixels of the pixel unit 11 share the same second sub-pixel 111. As a result, the resolution can be improved and the limitation of FMM technology can be overcome.

In the pixel arrangement structure of the present disclosure, in two of the adjacent pixel units 11, sub-pixels in the same color are neighbored so that the problem of mixed color can be prevented.

In the pixel arrangement structure of the present disclosure, the first sub-pixel 111 is blue sub-pixel, the second sub-pixel 112 is red sub-pixel, and the third sub-pixel 113 is green sub-pixel. An area of the first sub-pixel 111 is greater than areas of the second sub-pixel 112 and the third sub-pixel 113. The area of blue sub-pixel is greatest so that the efficient usage time of blue light component is prolonged. On the other hand, the luminous strength of blue sub-pixel is weakest. The luminous strength is enhanced by enlarging the area of blue sub-pixel.

In the present embodiment, the luminous strength of the first sub-pixel 111 is averaged from luminous of the four pixels sharing the same first sub-pixel 111. The luminous strength of the second sub-pixel 112 is averaged from luminous of the two pixels sharing the same second sub-pixel 112. Each pixel has independent green sub-pixel, thus the luminous strength of green sub-pixel is directly display.

The present disclosure further relates to a display panel includes a pixel arrangement structure. The pixel arrangement includes a plurality of pixel repeated combinations. Each of the pixel repeated combinations includes a plurality of pixel units.

The plurality of pixel units of the pixel repeated combination shares a sub-pixel and surrounds a center of the sub-pixel.

In the display panel of the present disclosure, the pixel unit includes two pixels disposed back to back. Each of the pixels includes a first sub-pixel.

In the pixel unit, one of the first sub-pixel disposes at the center of the pixel repeated combination and the other first sub-pixel is distant from the center of the pixel repeated combination.

In the pixel repeated combinations, the plurality of pixel units share one first sub-pixels disposed at center are of the repeated combinations.

In the display panel of the present disclosure, each of the pixel repeated combinations includes four pixel units. A shape of the pixel repeated combination is quadrangle. The four pixel units are disposed in areas formed by two midlines of the pixel repeated combinations. The four pixel units are radially symmetrical to a cross over point of the two midlines of the pixel repeated combinations.

In the display panel of the present disclosure, a shape of the repeated combinations is rhombus having all right angles, a shape of the pixel unit is rhombus having all right angles, and a shape of the first sub-pixel is square.

In the display panel of the present disclosure, each of the pixels of the pixel unit includes a second sub-pixel and a third sub-pixel disposed between the first sub-pixel and the second sub-pixel. A shape of the second sub-pixel is a hexagon and a shape of the third sub-pixel is an isosceles trapezoid.

In each of the pixel units, two of the pixels of share the second sub-pixel. Two of the pixels are symmetrical on a basis of a central axis of the second sub-pixel.

In the display panel of the present disclosure, sub-pixels of two adjacent pixel units in the same color are adjacent to each other.

In the display panel of the present disclosure, the first sub-pixels are blue sub-pixels, the second sub-pixels are red sub-pixels, and the third sub-pixels are green sub-pixel.

In the display panel of the present disclosure, an area of the first sub-pixel is greater than an area of the second sub-pixel and the third sub-pixel.

In the display panel of the present disclosure, the luminous strength of the first sub-pixel is averaged from luminous of the four pixels sharing the same first sub-pixel. The luminous strength of the second sub-pixel is averaged from luminous of the two pixels sharing the same second sub-pixel.

In comparison of the pixel arrangement and display panel of the present technology, the numbers of the first sub-pixels in the pixel arrangement structure and the display panel are reduced by utilizing the present disclosure which makes pixels of the plurality of pixel unit share one first sub-pixel. As a result, the resolution is enhanced and limitation of FMM manufacture technology can be overcome. In addition, problems of mixed color can be avoided because sub-pixels in the same color are neighboring. In the meanwhile, the areas of blue sub-pixels are greatest so that the efficient usage time of blue-light components is prolonged. Hence, problems of mix color and difficulty of manufacturing exist in the present technology during the manufacturing process for high-resolution display panel can be overcome.

To conclude, embodiments disclosed above are preferable embodiments rather than limitation of the present disclosure. Any changes and modifications can be completed by a skilled person in the art on the basis of the concept and the scope of the present disclosure. Therefore, the protected scope should base on the scope defined by claims in the present disclosure.

1. A pixel arrangement structure comprising a plurality of pixel repeated combinations, wherein each of the pixel repeated combinations comprises:
four pixel units, wherein each of the pixel unit comprises:
two pixels disposed back to back, wherein each of the pixel comprises first divisional sub-pixels, wherein two of the first divisional sub-pixels are disposed at a center of the repeated combination and distant from the center of the repeated combination respectively;
wherein the four pixel units disposed within four areas are divided by two diagonal lines of the repeated combination, and the four pixels are radially symmetrical to a midpoint of the diagonal lines of the repeated combination;
wherein four first divisional sub-pixels of the pixel units surrounding the center of the repeated combination integrally combine into a first sub-pixel;
wherein a shape of the pixel unit is a square, a shape of the first sub-pixel is a square.

2. The pixel arrangement structure according to claim 1, wherein each of the pixels of the pixel unit further comprises a second divisional sub-pixel and a third sub-pixel disposed between the first divisional sub-pixel and the second divisional sub-pixel;
wherein the second divisional sub-pixels of two of the pixels of the pixel units intergrade into a second sub-pixel, and two of the pixels are symmetrical on a basis of a central axis of the second sub-pixel, wherein a shape of the second sub-pixel is a hexagon, a shape of the third sub-pixel is an isosceles trapezoid.

3. The pixel arrangement structure according to claim 2, wherein the first sub-pixels, the second sub-pixels, or the third sub-pixels of two adjacent pixel units in the same color are adjacent to each other.

4. The pixel arrangement structure according to claim 2, wherein the first sub-pixel is a blue sub-pixel, the second sub-pixel is a red sub-pixel, and the third sub-pixel is a green sub-pixel.

5. The pixel arrangement structure according to claim 2, wherein an area of the first sub-pixel is greater than an area of the second sub-pixel, and also greater than an area of the third sub-pixel.

6. A pixel arrangement structure comprising a plurality of pixel repeated combinations, wherein each of the pixel repeated combinations comprises a plurality of pixel units;
wherein the plurality of pixel units of the pixel repeated combination share a first sub-pixel and surround a center of the first sub-pixel.

7. The pixel arrangement structure according to claim 6, wherein each of the pixel comprises first divisional sub-pixels, wherein two of the first divisional sub-pixels are disposed at a center of the repeated combination and distant from the center of the repeated combination respectively; wherein the first divisional sub-pixels of the pixel units surrounding the center of the repeated combination integrally combine into a first sub-pixel.

8. The pixel arrangement structure according to claim 7, wherein each of the pixel repeated combinations comprises four pixel units, a shape the pixel repeated combination is quadrangle, and the four pixel units are disposed within four areas are divided by two diagonal lines of the repeated combination, and the four pixels are radially symmetrical to a midpoint of the diagonal lines of the repeated combination.

9. The pixel arrangement structure according to claim 7, wherein a shape of the pixel repeated combination is a square, a shape of the pixel unit is a square, and a shape of the first sub-pixel is square.

10. The pixel arrangement structure according to claim 7, wherein each of the pixels of the pixel unit further comprises a second divisional sub-pixel and a third sub-pixel disposed between the first divisional sub-pixel and the second divisional sub-pixel;
wherein the second divisional sub-pixels of two of the pixels of the pixel units intergrade into a second sub-pixel, and two of the pixels are symmetrical on a basis of a central axis of the second sub-pixel, wherein a shape of the second sub-pixel is a hexagon, a shape of the third sub-pixel is an isosceles trapezoid.

11. The pixel arrangement structure according to claim 10, wherein the first sub-pixels, the second sub-pixels, or the third sub-pixels of two adjacent pixel units in the same color are adjacent to each other.

12. The pixel arrangement structure according to claim 10, wherein the first sub-pixel is a blue sub-pixel, the second sub-pixel is a red sub-pixel, and the third sub-pixel is a green sub-pixel.

13. The pixel arrangement structure according to claim 12, wherein an area of the first sub-pixel is greater than an area of the second sub-pixel, and also greater than an area of the third sub-pixel.

14. A display panel comprising a pixel arrangement structure, wherein the pixel arrangement structure comprising a plurality of pixel repeated combinations, wherein each of the pixel repeated combinations comprises a plurality of pixel units;
wherein the plurality of pixel units of the pixel repeated combinations share a first sub-pixel and surround a center of the first sub-pixel.

15. The display panel according to claim 14, wherein the pixel unit further comprises two pixels disposed back to back, wherein each of the pixel comprises first divisional sub-pixels, wherein two of the first divisional sub-pixels are disposed at a center of the repeated combination and distant from the center of the repeated combination respectively;
wherein the four pixel units disposed within four areas are divided by two diagonal lines of the repeated combination, and the four pixels are radially symmetrical to a midpoint of the diagonal lines of the repeated combination;
wherein four first divisional sub-pixels of the pixel units surrounding the center of the repeated combination integrally combine into a first sub-pixel.

16. The display panel according to claim 15, wherein each of the pixel repeated combinations comprises four pixel units, a shape of the pixel repeated combination is quadrangle, wherein the four pixel units disposed within four areas are divided by two diagonal lines of the repeated combination, and the four pixels are radially symmetrical to a midpoint of the diagonal lines of the repeated combination.

17. The display panel according to claim 15, wherein a shape of the pixel repeated combination is a square, a shape of the pixel unit is a square, and a shape of the first sub-pixel is square.

18. The display panel according to claim 15, wherein each of the pixels of the pixel unit further comprises second divisional sub-pixel and a third sub-pixel disposed between the first divisional sub-pixel and the second divisional sub-pixel;
wherein the second divisional sub-pixels of two of the pixels of the pixel units intergrade into a second sub-pixel, and two of the pixels are symmetrical on a basis of a central axis of the second sub-pixel, wherein a shape of the second sub-pixel is a hexagon, a shape of the third sub-pixel is an isosceles trapezoid.

19. The display panel according to claim 18, wherein the first sub-pixels, the second sub-pixels, or the third sub-pixels of two adjacent repeated combinations in the same color are adjacent to each other.

20. The display panel according to claim 18, wherein the first sub-pixel is a blue sub-pixel, the second sub-pixel is a red sub-pixel, and the third sub-pixel is a green sub-pixel.
